(19) United States
(12) Patent Application Publication
(10) Pub. No.: US 2025/0280530 A1
(43) Pub. Date: Sep. 4, 2025

(54) CELL SENSING STRUCTURE AND METHODS OF FORMATION

(71) Applicant: Micron Technology, Inc., Boise, ID (US)

(72) Inventors: Ahmed M. ELSIED, Boise, ID (US); Jaidah MOHAN, Boise, ID (US); Kamal K. MUTHUKRISHNAN, Boise, ID (US); Albert P. CHAN, Boise, ID (US); Jerome IMONIGIE, Meridian, ID (US); Kevin J. TOREK, Meridian, ID (US); Jignesh SONI, Boise, ID (US)

(21) Appl. No.: 19/050,041

(22) Filed: Feb. 10, 2025

Related U.S. Application Data
(60) Provisional application No. 63/559,808, filed on Feb. 29, 2024.

(51) Int. Cl. H10B 12/00

(52) U.S. Cl. CPC H10B 12/482; H10B 12/02; H10B 12/315

(57) ABSTRACT

Implementations described herein relate to various structures, integrated assemblies, and memory devices. In some implementations, a structure includes a semiconductor layer, a dielectric layer that is proximate to the semiconductor layer, and a multi-layer structure that extends away from an approximately planar surface across the semiconductor layer and the dielectric layer. The multi-layer structure includes a planarized tip region and an outer silicon nitride layer that extends from the approximately planar surface to the planarized tip region. In some implementations, a portion of the outer silicon nitride layer in the planarized tip region is adulterated. The structure further includes a conductive structure proximate to the multi-layer structure that includes a portion that extends through the approximately planar surface and that has a tip with an anisotropic morphology. In some implementations, the anisotropic morphology includes a profile traversing into a portion of the semiconductor layer and into a portion of the dielectric layer.

### CROSS-REFERENCE TO RELATED APPLICATION

This Patent Application claims priority to U.S. Provisional Patent Application No. 63/559,808, filed on Feb. 29, 2024, entitled “CELL SENSING STRUCTURE AND METHODS OF FORMATION,” and assigned to the assignee hereof. The disclosure of the prior Application is considered part of and is incorporated by reference into this Patent Application.

### TECHNICAL FIELD

The present disclosure generally relates to semiconductor devices and methods of forming semiconductor devices. For example, the present disclosure relates to a cell sensing structure for a memory device.

### BACKGROUND

Memory devices are widely used to store information in various electronic devices. A memory device includes memory cells. A memory cell is an electronic circuit capable of being programmed to a data state of two or more data states. For example, a memory cell may be programmed to a data state that represents a single binary value, often denoted by a binary “1” or a binary “0.” As another example, a memory cell may be programmed to a data state that represents a fractional value (e.g., 0.5, 1.5, or the like). To store information, the electronic device may write, or program, a set of memory cells. To access the stored information, the electronic device may read, or sense, the stored state from the set of memory cells.

Various types of memory devices exist, including random access memory (RAM), read only memory (ROM), dynamic RAM (DRAM), static RAM (SRAM), synchronous dynamic RAM (SDRAM), ferroelectric RAM (FeRAM), magnetic RAM (MRAM), resistive RAM (RRAM), flash memory (e.g., NAND memory and NOR memory), and others. A memory device may be volatile or non-volatile. Non-volatile memory (e.g., flash memory) can store data for extended periods of time even in the absence of an external power source. Volatile memory (e.g., DRAM) may lose stored data over time unless the volatile memory is refreshed by a power source. A binary memory device may, for example, include a charged or discharged capacitor. A charged capacitor may, however, become discharged over time through leakage currents, resulting in the loss of the stored information. Some features of volatile memory may offer advantages, such as faster read or write speeds, while some features of non-volatile memory, such as the ability to store data without periodic refreshing, may be advantageous.

### BRIEF DESCRIPTION OF THE DRAWINGS

FIG. 1 is a circuit diagram of an example memory cell described herein.

FIG. 2 is a diagrammatic view of a cell sensing structure described herein.

FIG. 3 is a flowchart of an example method of forming an integrated assembly or memory device having the cell sensing structure.

FIGS. 4A through 4H are diagrammatic views showing formation of the structure at example process stages of an example process of forming the cell sensing structure.

FIG. 5 is a diagrammatic view of example etch operations described herein.

FIG. 6 is a diagrammatic view of an example memory device described herein.

### DETAILED DESCRIPTION

In a semiconductor device, a DRAM memory cell may be accessed using a combination of conductive structures that include a digit line structure and a cell contact structure. The digit line structure and the cell contact structure may be above an underlying active area of the semiconductor device (e.g., an area of the semiconductor device including active circuitry such as a transistor including source and/or drain regions). Techniques to fabricate the digit line structure and the cell contact structure may include using a series of semiconductor manufacturing operations to sequentially deposit, pattern, and/or etch a combination of conductive and/or dielectric layers over the underlying active area.

In some cases, the digit line structure is formed prior to the cell contact structure. Forming the digit line structure may include forming a multi-layer structure that includes one or more dielectric layers that electrically isolate a conductive layer (e.g., a digit line) of the digit line structure from another conductive layer of an adjacent digit line structure. Forming the multi-layer structure may further include forming a cap over a tip of the digit line structure and footings that protrude laterally from a base of the digit line structure directly over the underlying active area.

After the digit line structure is formed, an etch operation may be used to punch a cavity through the footings and into the active area for formation of the cell contact structure. However, while forming the cavity, the etch operation may thin and/or remove the cap. The thinning and/or removal of the cap may reduce process windows of subsequent semiconductor processing operations (e.g., subsequent etch operations used to form additional features of the semiconductor device), causing the digit line structure to be susceptible to additional material removal that eventually exposes the conductive layer to cause a potential of electrical shorting and reduce a quality and/or reliability of the semiconductor device.

Some implementations described herein include a semiconductor device that includes a cell sensing structure having a digit line structure and an adjacent cell contact structure. Techniques to form the digit line structure include forming a multi-layer structure including a cap portion and a footer portion that extends from a base of the multi-layer structure, where an outermost layer of the cap portion is doped with impurities (e.g., adulterated). During a punch operation that removes the footer portion and forms a cavity for a cell contact structure in an underlying active area, the outermost layer of the cap portion that is doped with impurities has an etch rate that is less than an etch rate of the footer portion and/or the underlying active area.

In this way, the cap portion is preserved to increase a process margin associated with subsequent formation of one or more additional features of the semiconductor device, thereby reducing a likelihood of the conductive layer being exposed through removal of materials included in one or more layers of the digit line structure. Furthermore, and by reducing the likelihood of the conductive layer being exposed, a potential of electrical shorting within the semiconductor device is reduced, to improve a quality and/or a reliability of the semiconductor device, thereby reducing an amount of resources (e.g., raw materials, labor, semiconductor processing tools, and/or computing resources) used to support a market consuming the semiconductor device.

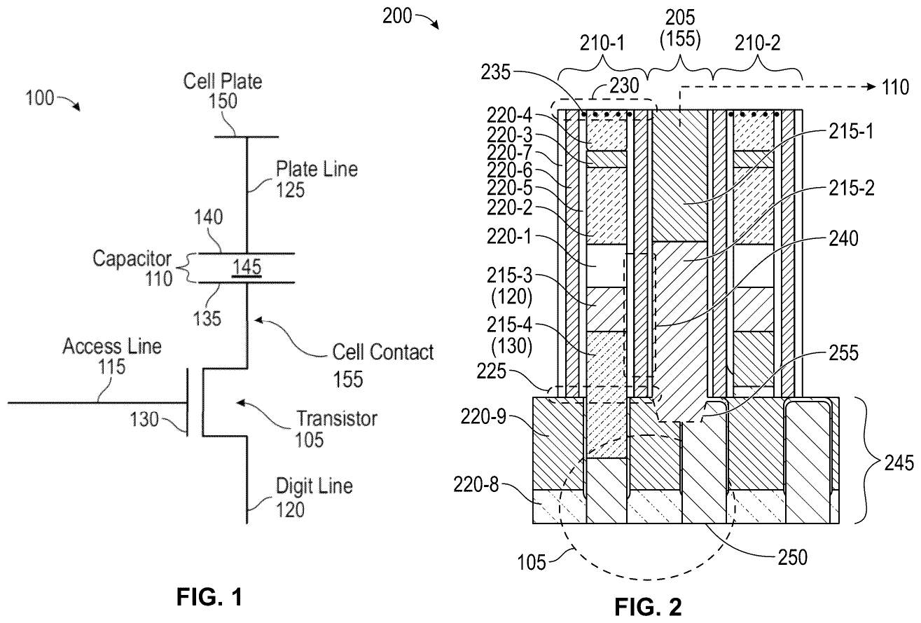

FIG. 1 is a circuit diagram of an example memory cell 100 described herein. In some implementations, the memory cell 100 is a ferroelectric memory cell.

Alternatively, the memory cell 100 may be a linear dielectric memory cell or a paraelectric memory cell. As shown in FIG. 1, the memory cell 100 may include a transistor 105 (or another type of selection circuit) and a capacitor 110. The memory cell 100 may be accessed (e.g., written to, read from, and/or erased) using signals on a combination of lines that are coupled to the memory cell 100, shown as an access line 115 (sometimes called a “word line”), a digit line 120 (sometimes called a “bit line”), and a plate line 125.

The transistor 105 (sometimes called an access transistor) may include a gate 130. The capacitor 110 includes a bottom electrode 135 and a top electrode 140 separated by an insulator 145. In some implementations, the capacitor is a ferroelectric capacitor, and the insulator 145 is a ferroelectric insulator that comprises, consists of, or consists essentially of ferroelectric material. Alternatively, the capacitor may be a linear dielectric capacitor, and the insulator 145 may be a linear dielectric insulator that comprises, consists of, or consists essentially of linear dielectric material. Alternatively, the capacitor may be a paraelectric capacitor, and the insulator 145 may be a paraelectric insulator that comprises, consists of, or consists essentially of paraelectric material. When the access line 115 is activated (e.g., when a voltage is applied to the access line 115), the gate 130 coupled to the access line 115 may be activated. When the gate 130 is activated, the transistor 105 couples the digit line 120 to the bottom electrode 135 of the capacitor 110. A state of the memory cell 100 may then be written or read via the digit line 120.

The top electrode 140 of the capacitor 110 may be coupled to the plate line 125 and a cell plate 150. To write to (or program) the memory cell 100, the access line 115 may be activated, and a voltage may be applied across the capacitor 110 by controlling the voltage of the top electrode 140 (via the plate line 125 and/or the cell plate 150) and/or the bottom electrode 135 (via the digit line 120).

In some implementations, data may be stored using the capacitor 110 by controlling a voltage difference and/or a polarity difference of the capacitor 110 (e.g., of the insulator 145 between the bottom electrode 135 and the top electrode 140). For example, a voltage of the cell plate 150 and the digit line 120 may be controlled. In some implementations, a negative polarity of the insulator 145 as compared to the cell plate 150 results in a logic “0” state being stored in the capacitor 110, and a positive polarity of the insulator 145 as compared to the cell plate 150 results in a logic “1” state being stored in the capacitor 110. For a linear dielectric capacitor or a paraelectric capacitor, the cell plate 150 may grounded, and the capacitor 110 may be charged by applying a voltage to the bottom electrode 135 via the digit line 120.

To read the memory cell 100 (e.g., a state stored by the capacitor 110), the access line 115 may be activated, and a voltage may be applied to the plate line 125. Applying a voltage to the plate line 125 may cause a change in the stored charge on the capacitor 110. The magnitude of the change in stored charge may depend on the stored state of capacitor 110 (e.g., whether the stored state is a logic “1” state or a logic “0” state). This may or may not induce a threshold change in the voltage of the digit line 120 based on the charge stored on the capacitor 110. The change in voltage or lack of change in voltage of the digit line 120 (or a magnitude of the change in voltage) may be used to determine the stored state of the capacitor 110. For example, if the change in voltage satisfies a threshold, then the read operation indicates that a first state was stored in the capacitor 110, whereas if the change in voltage does not satisfy the threshold, then the read operation determines that a second state was stored in the capacitor 110. In some cases, multiple threshold voltages may be used, such as when the capacitor is capable of storing more than two data states (e.g., for a multi-level cell, a triple-level cell, and so on).

In some implementations, the memory cell 100 is accessed using a cell contact 155 that is part of a connection between the transistor 105 and the capacitor 110. As described in greater detail in connection with FIGS. 2-6, the cell sensing structure may include the digit line 120 and the cell contact 155. The cell sensing structure may be a multi-layer structure having a combination of dielectric layers and conductive layers and include a first structure that includes the digit line 120 and a second, adjacent structure that includes the cell contact 155. The first structure (e.g., a digit line structure) may include a tip region having a cap portion that covers, protects, and/or electrically isolates the digit line 120. During fabrication of the cell contact 155, preservation of the cap portion is crucial to prevent electrical shorting of the digit line 120 with other conductive structures and/or integrated circuitry in a semiconductor device including the memory cell 100.

As indicated above, FIG. 1 is provided as an example. Other examples may differ from what is described with respect to FIG. 1.

FIG. 2 is a diagrammatic view of a cell sensing structure 200 described herein. The cell sensing structure 200 may be part of an integrated assembly, such as a memory array, a portion of a memory array, or a dynamic random access memory device that includes the memory array and one or more other components (e.g., sense amplifiers, a row decoder, a column decoder, a row address buffer, a column address buffer, one or more data buffers, one or more clocks, one or more counters, and/or a memory controller).

The cell sensing structure 200 (e.g., a multi-layer cell sensing structure) may include combinations of one or more semiconductive materials (e.g., one or more semiconductor layers), dielectric materials (e.g., one or more dielectric layers), and/or conductive materials (e.g., one or more conductive layers). Semiconductive materials may comprise, consist of, or consist essentially of silicon (e.g., polycrystalline silicon), silicon germanium, gallium arsenide, indium phosphide, gallium nitride, silicon carbide, or a type III-V element, among other examples. Dielectric materials may comprise, consist of, or consist essentially of silicon dioxide, silicon nitride, silicon oxycarbide, and/or aluminum dioxide, among other examples. Conductive materials may comprise, consist of, or consist essentially of a metal (e.g., titanium, tungsten, cobalt, nickel, platinum, and/or ruthenium), a metal composition (e.g., a metal silicide, a metal carbide, and/or a metal nitride, such as titanium nitride or titanium silicon nitride), and/or a conductively-doped semiconductive material.

The cell sensing structure 200 includes a contact structure 205 (e.g., a conductive structure including the cell contact 155 of FIG. 1) between multi-layer structures 210-1 and 210-2 (e.g., between digit line structures). The contact structure 205 includes combinations and/or portions of conductive layers. For example, and as shown in FIG. 2, the contact structure 205 includes a conductive layer 215-1 that is on and/or under a conductive layer 215-2. Furthermore, the contact structure 205 electrically couples with a capacitor (e.g., the capacitor 110 of FIG. 1).

Each of the multi-layer structures 210-1 and 210-2 may include combinations and/or portions of conductive layers, semiconductive layers, and/or dielectric layers. Using the multi-layer structure 210-1 as an example, and as shown in FIG. 2, the multi-layer structure 210 includes the conductive layer 215-3 (e.g., corresponding to the digit line 120 of FIG. 1) that is on and/or over the conductive layer 215-4 (e.g., corresponding to a portion of the gate 130 of FIG. 1).

The multi-layer structure 210-1 may further include dielectric layers 220-1, 220-2, 220-3, 220-4, 220-5, 220-6, and 220-7. One or more of the dielectric layers 220-1 through 220-7 may be over and/or on the conductive layers 215-3 and 215-4, and electrically insulate the conductive layers 215-3 and 215-4 (e.g., prevent electrical shorting between the conductive layers 215-3 and 215-4 and integrated circuitry, or other conductive layers, of a semiconductor device including the cell sensing structure 200). In some implementations, the dielectric layer 220-7 is an outer layer that includes a silicon nitride material (e.g., the dielectric layer 220-7 is an outer silicon nitride layer).

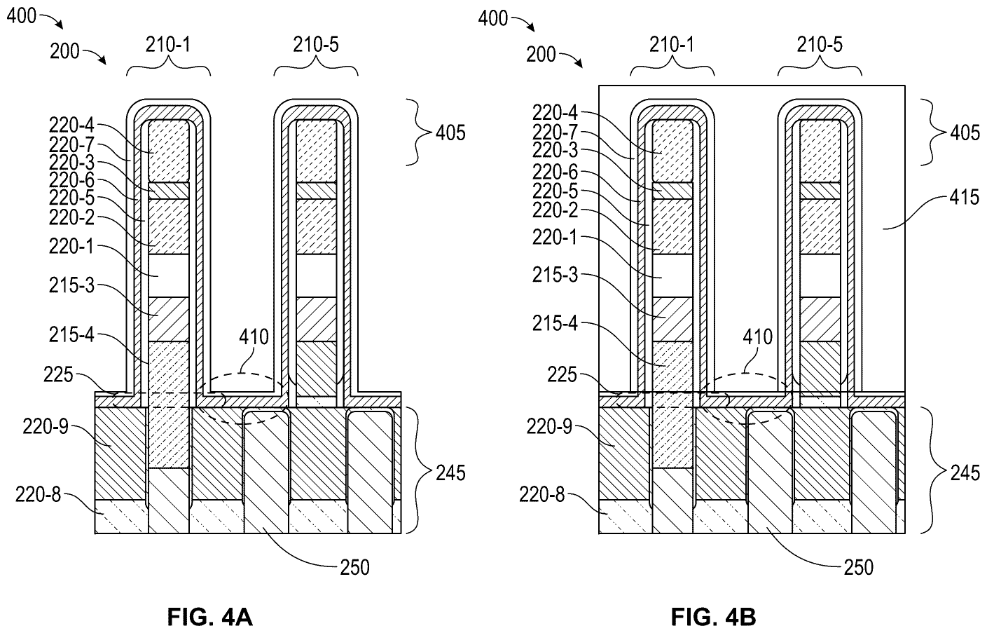

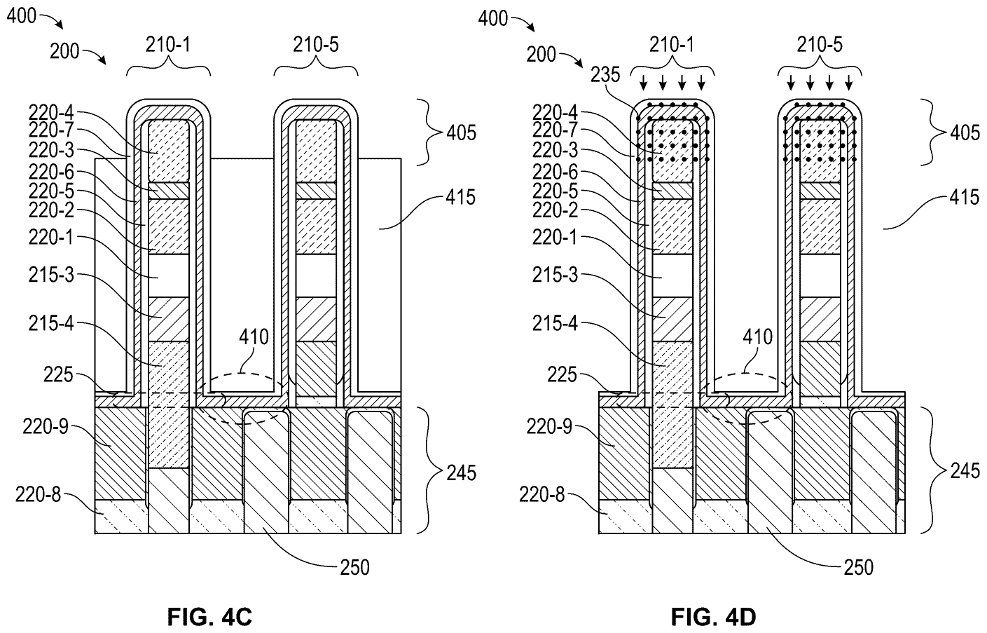

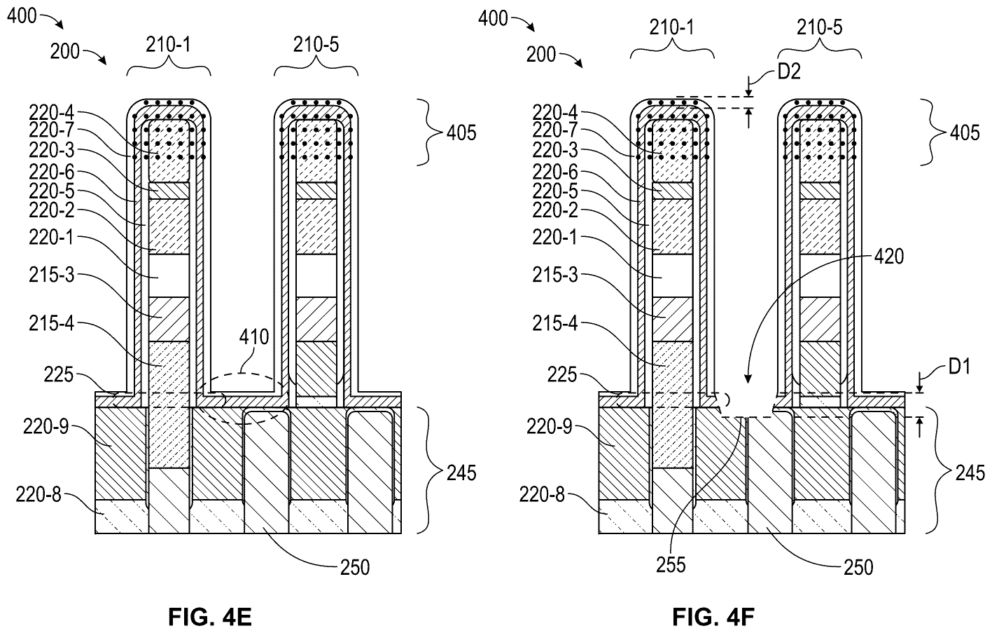

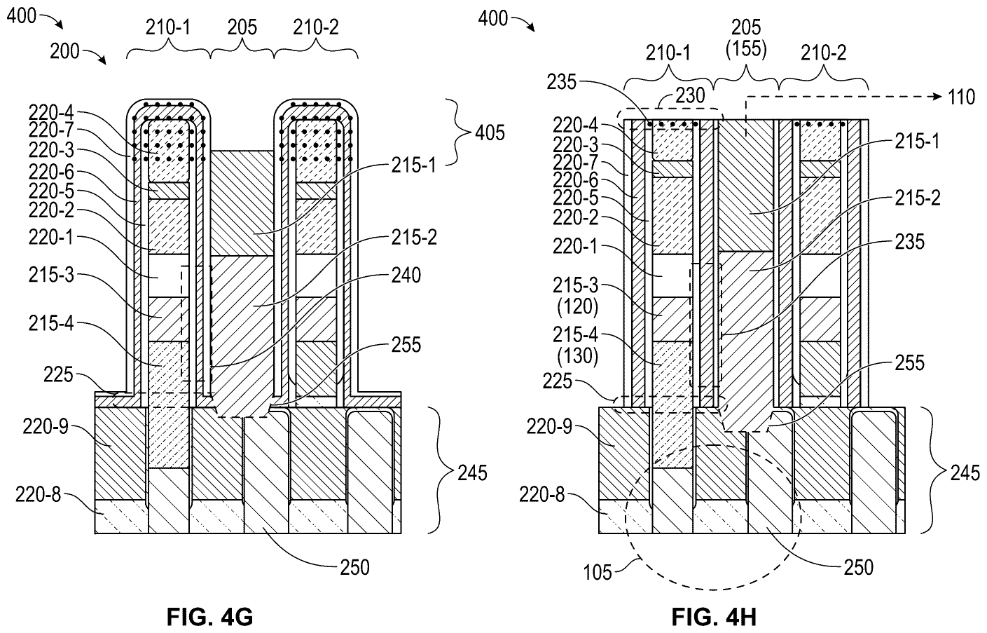

As further shown in FIG. 2, the multi-layer structure 210-1 has a base region 225 and a planarized tip region 230. The planarized tip region 230 (e.g., a distal tip of the multi-layer structure 210-1) may be away from the base region 225. As described in greater detail in connection with FIGS. 4A through 4H and elsewhere herein, one or more layers included in the planarized tip region 230 (e.g., one or more of the dielectric layers 220-4, 220-5, 220-6, and/or 220-7) may include impurities 235 (e.g., carbon dopants) that remain from a doping operation that dopes a cap portion of the multi-layer structure 210-1 to preserve the cap portion (e.g., including the dielectric layer 220-7 in the cap portion) during one or more etching operations. In other words, portions of tone or more dielectric layers in the planarized tip region 230 may be adulterated (e.g., may include dopants and/or other impurities that, within reasonable manufacturing limits, are intentionally formed within the one or more dielectric layers).

Portions of the dielectric layers 220-5, 220-6, and 220-7 may have different arrangements throughout the multi-layer structure 210-1. For example, the dielectric layers 220-5, 220-6, and/or 220-7 may each extend from the base region 225 to the planarized tip region 230. Further, and in some implementations, portions of the dielectric layers 220-5, 220-6, and/or 220-7 within the planarized tip region 230 are unadulterated (e.g., portions of the dielectric layers 220-5, 220-6, and/or 220-7 within the planarized tip region 230 may, within reasonable process control capabilities, be free of dopants and/or other impurities that are intentionally formed within and/or on the layers 220-5, 220-6, and/or 220-7 to alter and/or change one or more physical properties of the dielectric layers 220-5, 220-6, and/or 220-7).

As further shown in FIG. 2, portions of the dielectric layers 220-5, 220-6, and 220-7 between the base region 225 and the planarized tip region 230 may combine to form a multi-layer sidewall structure 240 (e.g., a vertical sidewall structure). In some implementations, the multi-layer sidewall structure 240 is between the conductive layer 215-3 (e.g., a digit line) and the contact structure 205 (e.g., a cell contact structure).

A device region 245 that includes one or more active devices (e.g., the transistor 105 of FIG. 1) may be proximate (e.g., under) the base region 225. As shown in FIG. 2, the device region 245 includes a dielectric layer 220-8, a dielectric layer 220-9, and a semiconductor layer 250. In some implementations, the dielectric layer 220-9 and the semiconductor layer 250 share an approximately planar surface (e.g., a top surface) that extends across the base region 225.

In some implementations, the semiconductor layer 250 is an active region (e.g., an active area) that includes one or more portions of a transistor device (e.g., a source/drain region of the transistor 105). Additionally, or alternatively and in some implementations, the dielectric layer 220-9 is an insulative region (e.g., insulative area) between one or more active areas of the device region 245.

As shown in FIG. 2, the contact structure 205 (e.g., the conductive layer 215-2) extends into the semiconductor layer 250 (e.g., the cell contact 155 makes an electrical connection with the transistor 105). In some implementations, the contact structure 205 extends into the dielectric layer 220-9 (e.g., extends into the dielectric layer 220-9 that is proximate and/or laterally adjacent to the semiconductor layer 250). Additionally, or alternatively and in some implementations, the contact structure 205 is approximately parallel to the dielectric layer 220-7.

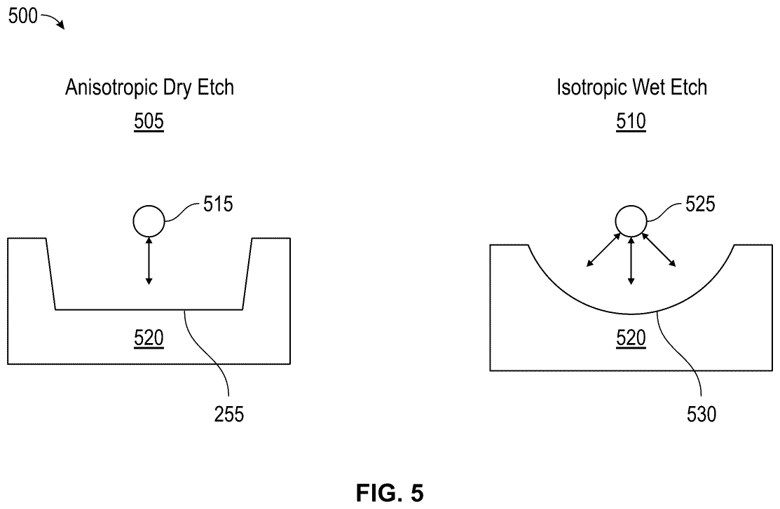

As further shown in FIG. 2, and as described in greater detail in connection with FIG. 5, a tip of the contact structure 205 includes an anisotropic morphology 255. The anisotropic morphology 250 includes a profile that traverses into portions of the dielectric layer 220-9 and the semiconductor layer 250. In some implementations, an inflection point at which the contact structure 205 transitions to the anisotropic morphology (e.g., an inflection point near the tip) aligns with an outer surface of the dielectric layer 220-7.

The multi-layer structure 210-2 may be similar to the multi-layer structure 210-1. For example, the multi-layer structure 210-2 may include one or more of the dielectric layers 220-1 through 220-7 and the conductive layer 215-3. Additionally, or alternatively, the multi-layer structure 210-2 may include additional dielectric layers and/or exclude the conductive layer 215-4.

As indicated above, FIG. 2 is provided as an example. Other examples may differ from what is described with regard to FIG. 2.

As described in connection with FIGS. 1 and 2, and in some implementations, a structure (e.g., the cell sensing structure 200) includes a semiconductor layer (e.g., the semiconductor layer 250), a dielectric layer (e.g., the dielectric layer 220-9) that is proximate to the semiconductor layer, and a multi-layer structure (e.g., the multi-layer structure 210-1) that extends away from an approximately planar surface (e.g., the base region 225) that is across the semiconductor layer and the dielectric layer. The multi-layer structure includes a planarized tip region (e.g., the planarized tip region 230) and an outer silicon nitride layer (e.g., the dielectric layer 220-7) that extends from the approximately planar surface to the planarized tip region. In some implementations, a portion of the outer silicon nitride layer in the planarized tip region is adulterated (e.g., includes the impurities 235). The cell sensing structure further includes a conductive structure proximate to the multi-layer structure that includes portion that extends through the approximately planar surface and that has a tip with an anisotropic morphology (e.g., the anisotropic morphology 255). In some implementations, the anisotropic morphology includes a profile traversing into a portion of the semiconductor layer and into a portion of the dielectric layer.

In some implementations, an apparatus (e.g., a memory device including the cell sensing structure) includes a device region (e.g., the device region 245) and a digit line structure that extends away from the device region. The digit line structure includes a base region (e.g., the base region 225), a planarized tip region (e.g., the planarized tip region 230) that is away from the base region; and a multi-layer structure (e.g., the multi-layer structure 210-1) including first dielectric layer that extends from the base region to the planarized tip region (e.g., the dielectric layer 220-5), a second dielectric layer (e.g., the dielectric layer 220-6) that conforms to the first dielectric layer and that extends from the base region to the planarized tip region, and a third dielectric layer (e.g., the dielectric layer 220-7) that conforms to the second dielectric layer and that extends from the base region to the planarized tip region. In some implementations, portions of the first dielectric layer, the second dielectric layer, and the third dielectric layer that are in the planarized tip region are adulterated (e.g., include the impurities 235). The apparatus further includes a cell contact structure (e.g., the cell contact structure 205) that is proximate to the digit line structure. The cell contact structure includes a tip that has an anisotropic morphology (e.g., the anisotropic morphology) and that extends beyond the base region and into an insulative area (e.g., the dielectric layer 220-9) and an active area (e.g., the semiconductor layer 250) within the device region. In some implementations, the anisotropic morphology includes a profile traversing into a portion of the insulative area and into a portion of the active area.

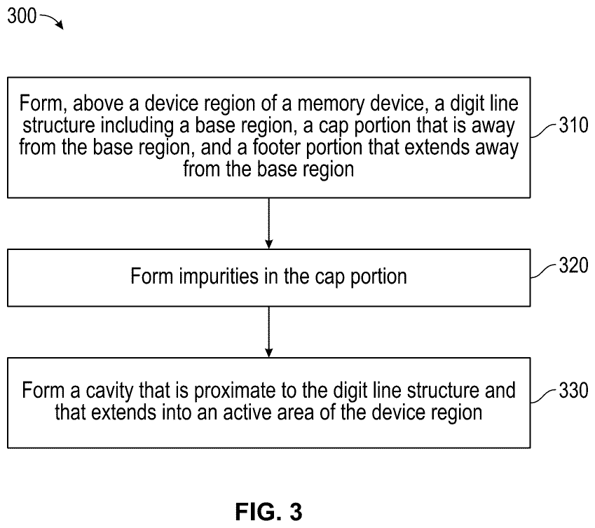

FIG. 3 is a flowchart of an example method 300 of forming an integrated assembly or memory device having a cell sensing structure described herein (e.g., the cell sensing structure 200). In some implementations, and as described in greater detail in connection with FIGS. 4A through 4H, one or more process blocks of FIG. 3 may be performed by various semiconductor manufacturing equipment.

As shown in FIG. 3, the method 300 may include forming, above a device region (e.g., the device region 245) of a memory device (e.g., the memory device 100), a digit line structure (e.g., the multi-layer structure 210-1) including a base region (e.g., the base region 225), a cap portion that is away from the base region, and a footer portion that extends from the base region (block 310). As further shown in FIG. 3, the method 300 may include forming impurities (e.g., the impurities 235) in the cap portion (block 320). As further shown in FIG. 3, the method 300 may include forming a cavity that is proximate to the digit line structure (e.g., adjacent to the digit line structure) and that extends into an active area of the device region (block 330).

The method 300 may include additional aspects, such as any single aspect or any combination of aspects described below and/or in connection with one or more other methods described elsewhere herein.

In a first aspect, the footer portion and the cap portion share a same outermost dielectric layer (e.g., the dielectric layer 220-7), and wherein forming the impurities in the cap portion reduces an etch rate of the outermost dielectric layer in the cap portion relative to an etch rate of the outermost dielectric layer in the footer portion.

In a second aspect, alone or in combination with the first aspect, forming impurities in the cap portion includes forming a mask structure (e.g., the mask structure 415) over the cap portion and the footer portion, removing a portion of the mask structure to expose the cap portion, and performing a doping operation that implants the impurities in the cap portion.

In a third aspect, alone or in combination with one or more of the first and second aspects, performing the doping operation that implants the impurities in the cap portion includes implanting carbon impurities in an outermost silicon nitride layer (E.g., the dielectric layer 220-7).

In a fourth aspect, alone or in combination with one or more of the first through third aspects, forming the mask structure over the cap portion and the footer portion includes forming a layer of a photoresist material over the cap portion and the footer portion.

In a fifth aspect, alone or in combination with one or more of the first through fourth aspects, forming the mask structure over the cap portion and the footer portion includes forming a hard mask structure over the cap portion and the footer portion.

In a sixth aspect, alone or in combination with one or more of the first through fifth aspects, removing the portion of the mask structure to expose of the cap portion includes removing the portion of the mask structure using a timed wet etch operation.

In a seventh aspect, alone or in combination with one or more of the first through sixth aspects, forming the cavity includes forming the cavity using an etch operation, wherein the etch operation uses an etchant that removes the footer portion and retains the cap portion.

In an eighth aspect, alone or in combination with one or more of the first through seventh aspects, forming the cavity using the etch operation includes forming the cavity using a punch operation, wherein the punch operation is a dry etch operation that forms an anisotropic morphology (e.g., the anisotropic morphology 255) at a bottom surface of the cavity.

In a ninth aspect, alone or in combination with one or more of the first through eighth aspects, the method 300 includes performing a planarization operation to the multi-layer structure, wherein the planarization operation is performed at a depth that removes the cap portion and leaves traces of the impurities in a planarized tip region (e.g., the planarized tip region 230).

Although FIG. 3 shows example blocks of the method 300, in some implementations, the method 300 may include additional blocks, fewer blocks, different blocks, or differently arranged blocks than those depicted in FIG. 3. In some implementations, the method 300 may include forming the cell sensing structure 200, an integrated assembly that includes the cell sensing structure 200, any part described herein of the cell sensing structure 200, and/or any part described herein of an integrated assembly that includes the cell sensing structure 200. For example, the method 300 may include forming one or more of the parts the memory cell 100, including the transistor 105, the digit line 120, and/or the cell contact 155.

FIGS. 4A through 4G are diagrammatic views showing formation of the cell sensing structure 200 at example process stages of an example process 400 of forming the cell sensing structure 200. In some implementations, the process 400 described below in connection with FIGS. 4A through 4G may correspond to the method 300 and/or one or more blocks of the method 300. However, the process described below is an example, and other example processes may be used to form the cell sensing structure 200, an integrated assembly that includes the cell sensing structure 200, and/or one or more parts of the cell sensing structure 200 and/or an integrated assembly including the cell sensing structure 200.

As illustrated in FIG. 4A, the process 400 includes forming the device region 245 with the multi-layer structures 210-1 and 210-2 that extend from the device region 245. Forming the device region 245 may include forming the semiconductor layer 250, the dielectric layer 220-8, and/or the dielectric layer 220-9 using a combination of deposition, photolithography, and etching techniques.

The multi-layer structures 210-1 and 210-2 include the dielectric layers 220-1 through 220-7. Forming the multi-layer structures 210-1 and 210-2 may include forming the dielectric layers 220-1 through 220-7 using a combination of deposition, photolithography, and etching techniques. In some implementations, forming the multi-layer structures 210-1 and 210-2 includes forming an outermost layer (e.g., the dielectric layer 220-7) using a deposition operation to form a layer of silicon nitride. In some implementations, forming the dielectric layer 220-7 includes forming the dielectric layer 220-7 as part of a cap portion 405.

As further illustrated in FIG. 4A, forming the multi-layer structures 210-1 and 210-2 includes forming a footer portion 410 that extends away from the base region 225. In some implementations, and as shown in FIG. 4A, forming the footer portion 410 includes forming a top segment (e.g., a portion of the layer 220-7) that is over and/or on a bottom segment (e.g., a portion of the layer 220-6).

As illustrated in FIG. 4B, the process 400 includes forming a mask structure 415 over the cap portion 405 and the footer portion 410 using one or more deposition techniques. As an example, forming the mask structure 415 may include using a spin coating operation to coat a layer of a photoresist material over and/or on the cap portion 405 and the footer portion 410. As another example, forming the mask structure 415 may include using a chemical vapor deposition (CVD) operation to form a layer of an oxide material (e.g., a hard mask structure) over and/or on the cap portion 405 and the footer portion 410. However, other techniques, operations, and/or materials that may be used to form the mask structure 415 are within the scope of the present disclosure.

As illustrated in FIG. 4C, the process 400 includes removing a portion of the mask structure 415 (e.g., recessing the mask structure 415) using one or more removal techniques to expose the cap portion 405. As an example, removing the portion of the mask structure 415 to expose the cap portion 405 may include using a timed wet etch operation. In such a case, the timed wet etch operation may retain a remainder of the mask structure 415 that is over and/or on the footer portion 410. However, other techniques and/or operations that may be used to remove the portion of the mask structure 415 to expose the cap portion 405 are within the scope of the present disclosure.

As illustrated in FIG. 4D, the process 400 includes forming the impurities 235 in the cap portion 405. As an example, forming the impurities 235 in the cap portion 405 may include using an implant operation to dope one or more dielectric layers (e.g., one or more of the dielectric layers 220-4, 220-5, 220-6, and/or 220-7) included in the cap portion 405 with ions. In some implementations, the implant operation may use carbon ions as the impurities 235 that adulterate the one or more dielectric layers. However, other techniques, operations, and/or ions that may be used to form the impurities 235 are within the scope of the present disclosure.

The presence of the impurities 235 may reduce an etch rate of the dielectric layer 220-7 (an outermost layer) within the cap portion 405 relative to an etch rate of the dielectric layer 220-7 within the footer portion 410 (e.g., silicon nitride within the cap portion may be adulterated and silicon nitride within the footer portion may be unadulterated to cause a difference in etch rates). In this way, and as described in greater detail in connection with FIG. 4E, the cap portion 405 may be preserved during formation of a cavity in the device region 245.

As illustrated in FIG. 4E, the process 400 includes removing remaining portions of the mask structure 415 using one or more removal techniques to expose the footer portion 410. As an example, removing the remaining portions of the mask structure 415 to expose the footer portion 410 may include using a stripping and cleaning operation. However, other techniques and/or operations that may be used to remove the remaining portions of the mask structure 415 to expose the footer portion 410 are within the scope of the present disclosure.

As illustrated in FIG. 4F, the process 400 includes using one or more removal techniques to form a cavity 420 that penetrates into the semiconductor layer 250 (e.g., into an active area of the device region 245). As an example, forming the cavity 420 may include using a dry etch operation to “punch” through the footer portion 410 (e.g., punch through the dielectric layers 220-6 and 220-7) and into the device region 245. Further, and as described in greater detail in connection with FIG. 5, such a dry etch operation may form the anisotropic morphology 255 at a bottom surface of the cavity 420. However, other techniques and/or operations that may be used to form the cavity 420 are within the scope of the present disclosure.

As shown in FIG. 4F, the cavity 420 is formed proximate (e.g., adjacent to) to the multi-layer structure 210-1. Additionally, the cavity 420 is formed between the multi-layer structure 210-1 and the multi-layer structure 210-1.

In some implementations, the cavity 420 has a depth D1 and the dielectric layer 220-7 in the in the tip region 230 has a thickness D2, where the depth D1 is greater than the thickness D2. For example, the depth D1 may be approximately 15 nanometers and the thickness D2 may be approximately 3 nanometers. Additionally, or alternatively, a ratio of the depth D1 to the thickness D2 (D1:D2) may be approximately 5:1. If the thickness D2 is less than approximately 3 nanometers, or if the ratio D1:D2 is greater than approximately 5:1, a remaining amount of the dielectric layer 220-7 in the tip region 230 may be insufficient to prevent excessive damage to the multi-layer structure 210-1 (and/or the multi-layer structure 210-2) during subsequent manufacturing and/or processing of the cell sensing structure 200. However, other values and/or ratios associated with the depth D1 the thickness D2 are within the scope of the present disclosure.

As illustrated in FIG. 4G, the process 400 includes forming the contact structure 205 between the multi-layer structures 210-1 and 210-2. Techniques used to form the contact structure 205 may include using a deposition operation to deposit the conductive layers 215-1 and 215-2. However, other techniques and/or operations to form the contact structure 205 are within the scope of the present disclosure.

As illustrated in FIG. 4H, the cell sensing structure 200 is planarized. Techniques to planarize the cell sensing structure 200 may include using a chemical mechanical planarization (CMP) operation to planarize tips of the multi-layer structures 210-1 and 210-2 (e.g., planarize the digit line structures) and remove the cap portion(s) 405. Additionally, or alternatively and in some implementations, the CMP operation may remove portions of and/or planarize the conductive layer 215-1. However, after planarization and as shown in FIG. 4H, traces of the impurities 235 may remain in the planarized tip region 230 (e.g., in one or more of the dielectric layers 220-4, 220-5, 220-6, and/or 220-7).

As indicated above, the process 400 described in connection with FIGS. 4A through 4H is provided as an example. Other examples may differ from what is described with respect to FIGS. 4A through 4H. The structure shown in FIG. 4H may be equivalent to the cell sensing structure 200 described elsewhere herein. In process the process steps above that describe forming material, such material may be formed, for example, using chemical vapor deposition, atomic layer deposition, physical vapor deposition, or another deposition technique. In process steps above that describe removing material, such material may be removed, for example, using a wet etching technique (e.g., wet chemical etching), a dry etching technique (e.g., plasma etching), an ion etching technique (e.g., sputtering or reactive ion etching), atomic layer etching, or another etching technique.

As described in connection with FIGS. 3 and 4A through 4H, and in some implementations, a series of semiconductor manufacturing operations includes forming, above a device region (e.g., the device region 245) of a memory device (e.g., the memory device 100), a digit line structure (e.g., the multi-layer structure 210-1) including a base region (e.g., the base region 225), a cap portion (e.g., the cap portion 405) that is away from the base region, and a footer portion (e.g., the footer portion 410) that extends away from the base region. The series of semiconductor manufacturing operation includes forming impurities (e.g., the impurities 235) in the cap portion and forming a cavity (e.g., the cavity 420) that is proximate (e.g., adjacent to) the digit line structure and extends into an active area (e.g., the semiconductor layer 250) of the device region.

In this way, the cap portion is preserved to increase a process margin associated with subsequent formation of one or more additional features of the memory device, thereby reducing a likelihood of a conductive layer (e.g., the conductive layer 215-3) being exposed through removal of materials included in one or more layers of the digit line structure. Furthermore, and by reducing the likelihood of the conductive layer being exposed, a potential of electrical shorting within the memory device is reduced, to improve a quality and/or a reliability of the memory device, thereby reducing an amount of resources (e.g., raw materials, labor, semiconductor processing tools, and/or computing resources) used to support a market consuming the memory device.

FIG. 5 is a diagrammatic view of example etch operations 500 described herein. The etch operations 500 include an anisotropic dry etch operation 505 and an isotropic wet etch operation 510.

As part of the anisotropic dry etch operation 505, an etchant 515 may remove from a layer of 520 material in a single direction (e.g., the anisotropic dry etch operation does not remove material in all directions). The anisotropic dry etch operation 505 may form the anisotropic morphology 255 described in connection with FIGS. 2-4G and elsewhere. The anisotropic morphology 255 may include surfaces and/or sidewalls that have approximately planar and/or angled shapes.

As part of the isotropic wet etch operation 510 an etchant 525 may remove from the layer 520 material in multiple directions and form an isotropic morphology 530 (e.g., the isotropic wet etch operation 510 does not remove material in a single direction). The isotropic morphology 530 may include surfaces and/or sidewalls that have an approximately spherical, cylindrical, and/or curved shape.

As indicated above, FIG. 5 is provided as an example. Other examples may differ from what is described with respect to FIG. 5.

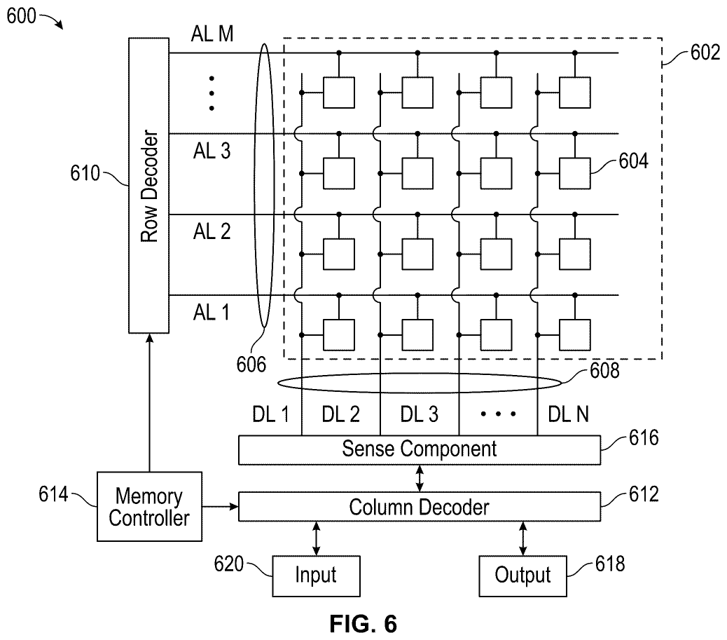

FIG. 6 is a diagrammatic view of an example memory device 600 described herein. The memory device 600 may include a memory array 602 that includes multiple memory cells 604. A memory cell 604 is programmable or configurable into a data state of multiple data states (e.g., two or more data states). For example, a memory cell 604 may be set to a particular data state at a particular time, and the memory cell 604 may be set to another data state at another time. A data state may correspond to a value stored by the memory cell 604. The value may be a binary value, such as a binary 0 or a binary 1, or may be a fractional value, such as 0.5, 1.5, or the like. A memory cell 604 may include a capacitor to store a charge representative of the data state. For example, a charged and an uncharged capacitor may represent a first data state and a second data state, respectively. As another example, a first level of charge (e.g., fully charged) may represent a first data state, a second level of charge (e.g., fully discharged) may represent a second data state, a third level of charge (e.g., partially charged) may represent a third data state, and so on.

Operations such as reading and writing (i.e., cycling) may be performed on memory cells 604 by activating or selecting the appropriate access line 606 (shown as access lines AL 1 through AL M) and digit line 608 (shown as digit lines DL 1 through DL N). An access line 606 may also be referred to as a “row line” or a “word line,” and a digit line 608 may also be referred to a “column line” or a “bit line.” Activating or selecting an access line 606 or a digit line 608 may include applying a voltage to the respective line. An access line 606 and/or a digit line 608 may comprise, consist of, or consist essentially of a conductive material, such as a metal (e.g., copper, aluminum, gold, titanium, or tungsten) and/or a metal alloy, among other examples. In FIG. 6, each row of memory cells 604 is connected to a single access line 606, and each column of memory cells 604 is connected to a single digit line 608. By activating one access line 606 and one digit line 608 (e.g., applying a voltage to the access line 606 and digit line 608), a single memory cell 604 may be accessed at (e.g., is accessible via) the intersection of the access line 606 and the digit line 608. The intersection of the access line 606 and the digit line 608 may be called an “address” of a memory cell 604.

In some implementations, the logic storing device of a memory cell 604, such as a capacitor, may be electrically isolated from a corresponding digit line 608 by a selection component, such as a transistor. The access line 606 may be connected to and may control the selection component. For example, the selection component may be a transistor, and the access line 606 may be connected to the gate of the transistor. Activating the access line 606 results in an electrical connection or closed circuit between the capacitor of a memory cell 604 and a corresponding digit line 608. The digit line 608 may then be accessed (e.g., is accessible) to either read from or write to the memory cell 604.

A row decoder 610 and a column decoder 612 may control access to memory cells 604. For example, the row decoder 610 may receive a row address from a memory controller 614 and may activate the appropriate access line 606 based on the received row address. Similarly, the column decoder 612 may receive a column address from the memory controller 614 and may activate the appropriate digit line 608 based on the column address.

Upon accessing a memory cell 604, the memory cell 604 may be read (e.g., sensed) by a sense component 616 to determine the stored data state of the memory cell 604. For example, after accessing the memory cell 604, the capacitor of the memory cell 604 may discharge onto its corresponding digit line 608. Discharging the capacitor may be based on biasing, or applying a voltage, to the capacitor. The discharging may induce a change in the voltage of the digit line 608, which the sense component 616 may compare to a reference voltage (not shown) to determine the stored data state of the memory cell 604. For example, if the digit line 608 has a higher voltage than the reference voltage, then the sense component 616 may determine that the stored data state of the memory cell 604 corresponds to a first value, such as a binary 1.

Conversely, if the digit line 608 has a lower voltage than the reference voltage, then the sense component 616 may determine that the stored data state of the memory cell 604 corresponds to a second value, such as a binary 0. The detected data state of the memory cell 604 may then be output (e.g., via the column decoder 612) to an output component 618 (e.g., a data buffer). A memory cell 604 may be written (e.g., set) by activating the appropriate access line 606 and digit line 608. The column decoder 612 may receive data, such as input from input component 620, to be written to one or more memory cells 604. A memory cell 604 may be written by applying a voltage across the capacitor of the memory cell 604.

The memory controller 614 may control the operation (e.g., read, write, re-write, refresh, and/or recovery) of the memory cells 604 via the row decoder 610, the column decoder 612, and/or the sense component 616. The memory controller 614 may generate row address signals and column address signals to activate the desired access line 606 and digit line 608. The memory controller 614 may also generate and control various voltages used during the operation of the memory array 602.

In some implementations, the memory device 600 includes the cell sensing structure 200 and/or an integrated assembly that includes the cell sensing structure 200. For example, the memory array 602 may include the cell sensing structure 200 and/or an integrated assembly that includes the cell sensing structure 200. Additionally, or alternatively, the memory cell 604 may include a memory cell described elsewhere herein.

As indicated above, FIG. 6 is provided as an example. Other examples may differ from what is described with respect to FIG. 6.

In some implementations, a structure includes a semiconductor layer; a dielectric layer that is proximate to the semiconductor layer; a multi-layer structure that extends away from an approximately planar surface that is across the semiconductor layer and the dielectric layer, comprising; a planarized tip region; and an outer silicon nitride layer that extends from the approximately planar surface to the planarized tip region, wherein a portion of the outer silicon nitride layer in the planarized tip region is adulterated; and a conductive structure proximate to the multi-layer structure, comprising: a portion that extends through the approximately planar surface and that has a tip with an anisotropic morphology, wherein the anisotropic morphology includes a profile traversing into a portion of the semiconductor layer and into a portion of the dielectric layer.

In some implementations, an apparatus includes a device region; a digit line structure that extends away from the device region, comprising: a base region; a planarized tip region that is away from the base region; and a multi-layer structure, comprising: a first dielectric layer that extends from the base region to the planarized tip region; a second dielectric layer that conforms to the first dielectric layer and that extends from the base region to the planarized tip region; a third dielectric layer that conforms to the second dielectric layer and that extends from the base region to the planarized tip region, wherein portions of the first dielectric layer, the second dielectric layer, and the third dielectric layer that are in the planarized tip region are adulterated; and a cell contact structure that is proximate to the digit line structure, comprising: a tip that has an anisotropic morphology and that extends beyond the base region and into an insulative area and an active area within the device region, wherein the anisotropic morphology includes a profile traversing into a portion of the insulative area and into a portion of the active area.

In some implementations, a method includes forming, above a device region of a memory device, a digit line structure including a base region, a cap portion away from the base region, and a footer portion extending away from the base region; forming impurities in the cap portion; and forming a cavity that is proximate to the digit line structure and extends into an active area of the device region.

The foregoing disclosure provides illustration and description but is not intended to be exhaustive or to limit the implementations to the precise forms disclosed. Modifications and variations may be made in light of the above disclosure or may be acquired from practice of the implementations described herein.

The orientations of the various elements in the figures are shown as examples, and the illustrated examples may be rotated relative to the depicted orientations. The descriptions provided herein, and the claims that follow, pertain to any structures that have the described relationships between various features, regardless of whether the structures are in the particular orientation of the drawings, or are rotated relative to such orientation. Similarly, spatially relative terms, such as “below,” “beneath,” “lower,” “above,” “upper,” “middle,” “left,” and “right,” are used herein for ease of description to describe one element's relationship to one or more other elements as illustrated in the figures. The spatially relative terms are intended to encompass different orientations of the element, structure, and/or assembly in use or operation in addition to the orientations depicted in the figures. A structure and/or assembly may be otherwise oriented (rotated 90 degrees or at other orientations), and the spatially relative descriptors used herein may be interpreted accordingly. Furthermore, the cross-sectional views in the figures only show features within the planes of the cross-sections, and do not show materials behind the planes of the cross-sections, unless indicated otherwise, in order to simplify the drawings.

As used herein, the terms “substantially” and “approximately” mean “within reasonable tolerances of manufacturing and measurement.” As used herein, “satisfying a threshold” may, depending on the context, refer to a value being greater than the threshold, greater than or equal to the threshold, less than the threshold, less than or equal to the threshold, equal to the threshold, not equal to the threshold, or the like. All ranges described herein are inclusive of numbers at the ends of those ranges, unless specifically indicated otherwise.

Even though particular combinations of features are recited in the claims and/or disclosed in the specification, these combinations are not intended to limit the disclosure of implementations described herein. Many of these features may be combined in ways not specifically recited in the claims and/or disclosed in the specification. For example, the disclosure includes each dependent claim in a claim set in combination with every other individual claim in that claim set and every combination of multiple claims in that claim set. As used herein, a phrase referring to “at least one of” a list of items refers to any combination of those items, including single members. As an example, “at least one of: a, b, or c” is intended to cover a, b, c, a+b, a+c, b+c, and a+b+c, as well as any combination with multiples of the same element (e.g., a+a, a+a+a, a+a+b, a+a+c, a+b+b, a+c+c, b+b, b+b+b, b+b+c, c+c, and c+c+c, or any other ordering of a, b, and c).

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Where only one item is intended, the phrase “only one,” “single,” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. As used herein, the term “multiple” can be replaced with “a plurality of” and vice versa. Also, as used herein, the term “or” is intended to be inclusive when used in a series and may be used interchangeably with “and/or,” unless explicitly stated otherwise (e.g., if used in combination with “either” or “only one of”).

What is claimed is:

1. A structure, comprising:
a semiconductor layer;
a dielectric layer that is proximate to the semiconductor layer;
a multi-layer structure that extends away from an approximately planar surface that is across the semiconductor layer and the dielectric layer, comprising;
a planarized tip region; and
an outer silicon nitride layer that extends from the approximately planar surface to the planarized tip region,
wherein a portion of the outer silicon nitride layer in the planarized tip region is adulterated; and
a conductive structure proximate to the multi-layer structure, comprising:
a portion that extends through the approximately planar surface and that has a tip with an anisotropic morphology,
wherein the anisotropic morphology includes a profile traversing into a portion of the semiconductor layer and into a portion of the dielectric layer.

2. The structure of claim 1, wherein the conductive structure is approximately parallel to the outer silicon nitride layer.

3. The structure of claim 1, wherein the outer silicon nitride layer extends from the approximately planar surface to the planarized tip region.

4. The structure of claim 1, wherein the outer silicon nitride layer is a portion of a multi-layer sidewall structure that is between a conductive layer of the multi-layer structure and the conductive structure.

5. The structure of claim 1, wherein an inflection point near the tip at which the conductive structure transitions to the anisotropic morphology aligns with an outer surface of the outer silicon nitride layer.

6. An apparatus, comprising:
a device region;
a digit line structure that extends away from the device region, comprising:
a base region;
a planarized tip region that is away from the base region; and
a multi-layer structure, comprising:
a first dielectric layer that extends from the base region to the planarized tip region;
a second dielectric layer that conforms to the first dielectric layer and that extends from the base region to the planarized tip region;
a third dielectric layer that conforms to the second dielectric layer and that extends from the base region to the planarized tip region,
wherein portions of the first dielectric layer, the second dielectric layer, and the third dielectric layer that are in the planarized tip region are adulterated; and
a cell contact structure that is proximate to the digit line structure, comprising:
a tip that has an anisotropic morphology and that extends beyond the base region and into an insulative area and an active area within the device region,
wherein the anisotropic morphology includes a profile traversing into a portion of the insulative area and into a portion of the active area.

7. The apparatus of claim 6, wherein the first dielectric layer, the second dielectric layer, and the third dielectric layer include portions that form a sidewall structure adjacent to a digit line of the digit line structure.

8. The apparatus of claim 6, wherein the active area corresponds to a source/drain region of a transistor device.

9. The apparatus of claim 6, wherein the cell contact structure connects with a capacitor of a dynamic random access memory device.

10. The apparatus of claim 6, wherein the digit line structure is a first digit line structure, and further comprising:
a second digit line structure adjacent to the first digit line structure, and
wherein the cell contact structure is between the second digit line structure and the first digit line structure.

11. A method, comprising:
forming, above a device region of a memory device, a digit line structure including a base region, a cap portion that is away from the base region, and a footer portion that extends from the base region;
forming impurities in the cap portion; and
forming a cavity that is proximate to the digit line structure and that extends into an insulative area and an active area of the device region.

12. The method of claim 11, wherein the footer portion and the cap portion share a same outermost dielectric layer, and wherein forming the impurities in the cap portion reduces an etch rate of the outermost dielectric layer in the cap portion relative to an etch rate of the outermost dielectric layer in the footer portion.

13. The method of claim 11, wherein forming impurities in the cap portion includes:
forming a mask structure over the cap portion and the footer portion;
removing a portion of the mask structure to expose the cap portion; and
performing a doping operation that implants the impurities in the cap portion.

14. The method of claim 13, wherein performing the doping operation that implants the impurities in the cap portion includes:
implanting carbon impurities in an outermost silicon nitride layer.

15. The method of claim 13, wherein forming the mask structure over the cap portion and the footer portion includes:
forming a layer of a photoresist material over the cap portion and the footer portion.

16. The method of claim 13, wherein forming the mask structure over the cap portion and the footer portion includes:
forming a hard mask structure over the cap portion and the footer portion.

17. The method of claim 13, wherein removing the portion of the mask structure to expose of the cap portion includes:
removing the portion of the mask structure using a timed wet etch operation.

18. The method of claim 11, wherein forming the cavity includes:
forming the cavity using an etch operation,
wherein the etch operation uses an etchant that removes the footer portion and retains the cap portion.

19. The method of claim 18, wherein forming the cavity using the etch operation includes:
forming the cavity using a punch operation,
wherein the punch operation is a dry etch operation that forms an anisotropic morphology at a bottom surface of the cavity.

20. The method of claim 11, further comprising:
performing a planarization operation to the digit line structure,
wherein the planarization operation is performed at a depth that removes the cap portion and leaves traces of the impurities in a planarized tip region.
